(19) United States
(12) Patent Application Publication
(10) Pub. No.: US 2007/0201595 A1
(43) Pub. Date: Aug. 30, 2007

(54) Clock recovery system

(76) Inventors: James R. Stimple, Santa Rosa, CA (US); Jady Palko, Windsor, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/361,603

(22) Filed: Feb. 24, 2006

(51) Int. Cl. H03D 3/24

(52) U.S. Cl. 375/376

(57) ABSTRACT

A clock recovery system includes a signal summer, a signal source, and an analog-to-digital converter (ADC) interposed in a phase locked loop (PLL). The ADC measures a calibration error signal with the signal source providing a stimulus signal to the signal summer, with a data signal applied to a phase detector within the PLL, and with the PLL in a phase locked state. One or more response characteristics of the PLL are determined based on the measured calibration error signal. The one or more response characteristics can be applied to measurements of a measurement error signal acquired by the ADC with the stimulus signal not provided to the signal summer, with the data signal applied to the phase detector, and with the PLL in the phase locked state.

### BACKGROUND OF THE INVENTION

Data signals in high speed digital communication systems are often transmitted without an accompanying clock signal. Receivers in these systems typically use clock recovery to extract or “recover” clock signals that are associated with the data signals. In phase-locked-loop (PLL)-based clock recovery systems, a clock signal is recovered from a transmitted data signal by locking the phase of an oscillator in the clock recovery system to the phase of edge transitions of digital bits within the data signal. The recovered clock signals provide timing information that enables receivers to accurately sample digital bits within the transmitted data signals. In digital communication analyzers (DCAs) and other types of measurement systems, recovered clock signals can be used as a trigger to enable the data signal to be sampled and presented on a display.

FIG. 1 shows an eye diagram representation of a data signal on the display of a DCA, showing the effects of signal fluctuations, or “jitter” on the data signal. The jitter on the eye diagram results from relative timing fluctuations or phase differences between the data signal and the recovered clock signal used to trigger the DCA. For frequencies of jitter that are well within the bandwidth of a PLL in the PLL-based clock recovery system, the phase of the data signal and the phase of the clock signal track each other, which results in the suppression of low frequency jitter on the eye diagram. At frequencies of jitter that are outside the bandwidth of the PLL, the phase of the data signal and phase of the clock signal do not track each other, which results in high frequency jitter being present on the eye diagram. Accordingly, the characteristics of the jitter present on the eye diagram provided by a DCA depend on the response characteristics of the PLL within the clock recovery system. This makes it difficult to accurately characterize jitter of a data signal applied to the DCA without also determining the response characteristics of the PLL under actual operating conditions of the PLL-based clock recovery system.

### BRIEF DESCRIPTION OF THE DRAWINGS

FIG. 1 shows an eye diagram representation of a data signal showing the effects of jitter on the data signal.

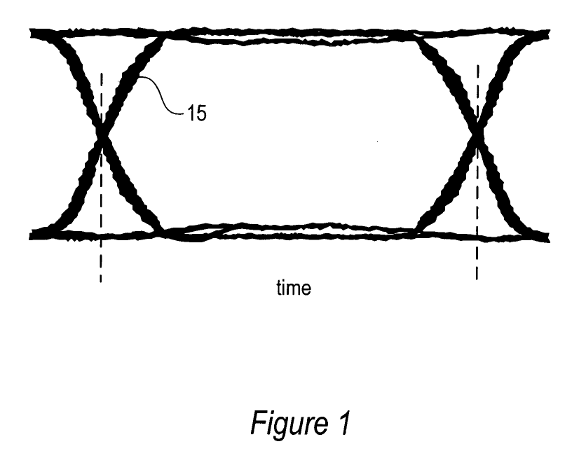

FIG. 2 shows one example of a clock recovery system according to embodiments of the present invention.

FIG. 3 shows an example of a clock recovery system according to alternative embodiments of the present invention.

FIGS. 4A-4C show examples of response characteristics of a clock recovery system according to embodiments of the present invention.

FIG. 5 shows an example frequency spectrum of jitter acquired with a clock recovery system according to embodiments of the present invention.

### DETAILED DESCRIPTION

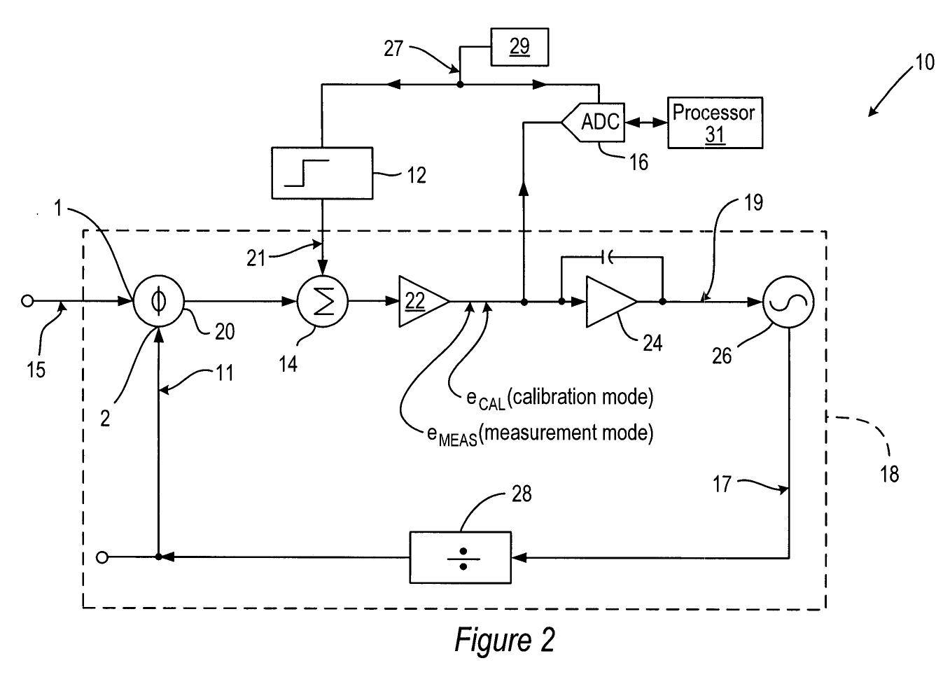

FIG. 2 shows one example of a clock recovery system 10 according to embodiments of the present invention. The clock recovery system 10 includes a signal source 12, a signal summer 14, and an analog-to-digital converter (ADC) 16 that are interposed within a phase-locked loop (PLL) 18. The PLL 18 in this example includes a phase detector 20, an error amplifier 22, a loop integrator 24, a voltage-controlled oscillator (VCO) 26 and a frequency divider 28 and is shown in block diagram form for the purpose of illustration. One example of a PLL 18 suitable for inclusion in the clock recovery system 10 is included in a model 83495 Clock Recovery Module provided by Agilent Technologies, Inc, of Palo Alto, Calif., USA. Alternative types of PLLs 18 that are suitable for recovering clock signals 11 from applied data signals 15 are included in alternative examples of the clock recovery system 10. The ADC 16 is shown coupled to the signal path between the signal summer 14 and the loop integrator 24 that in FIG. 2 also includes the error amplifier 22. 10181 Under phase-locked conditions, the PLL 18 included in the clock recovery system 10 operates in a conventional manner to provide a recovered clock signal 11 that is a frequency-divided version of a signal 17 provided by the VCO 26. The phase detector 20 in the PLL 18 provides an error signal that is present at the output of the error amplifier 22. The error signal represents differences in phase between the applied data signal 15 and the recovered clock signal 11. The error signal is applied to the loop integrator 24 which provides a drive signal 19 to the VCO 26 that adjusts the frequency of the VCO 26 to minimize the error signal. The PLL minimizes the error signal to the extent that the PLL 18 has sufficient gain and bandwidth to track signal fluctuations, or jitter, in the data signal 15. However, due to inherent gain and bandwidth limitations of the PLL 18, and operating characteristics of the phase detector 20, the phase of the clock signal 11 provided to an input 2 of the phase detector 20 cannot track high frequency fluctuations in the phase of the data signal 15. The extent of the phase tracking between the clock signal 11 and the data signal 15 depends on response characteristics, such as the loop gain and loop bandwidth of the PLL 18.

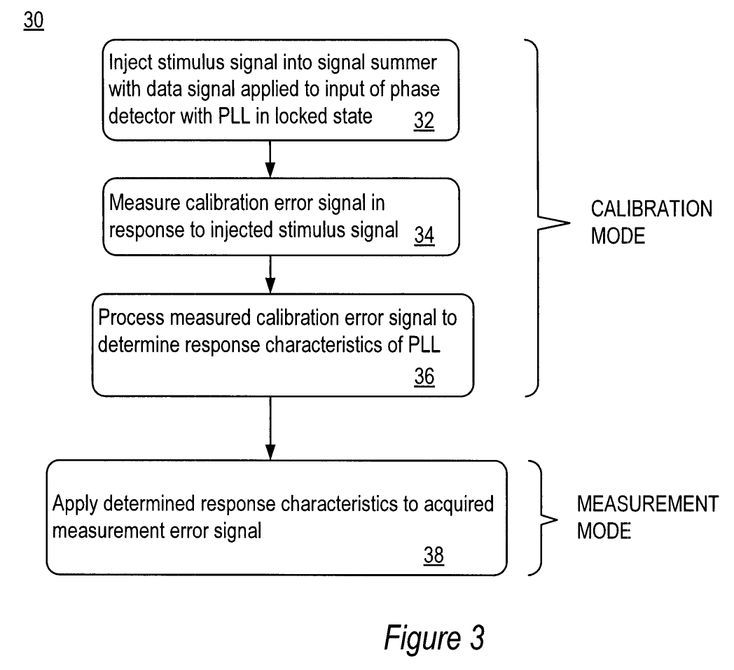

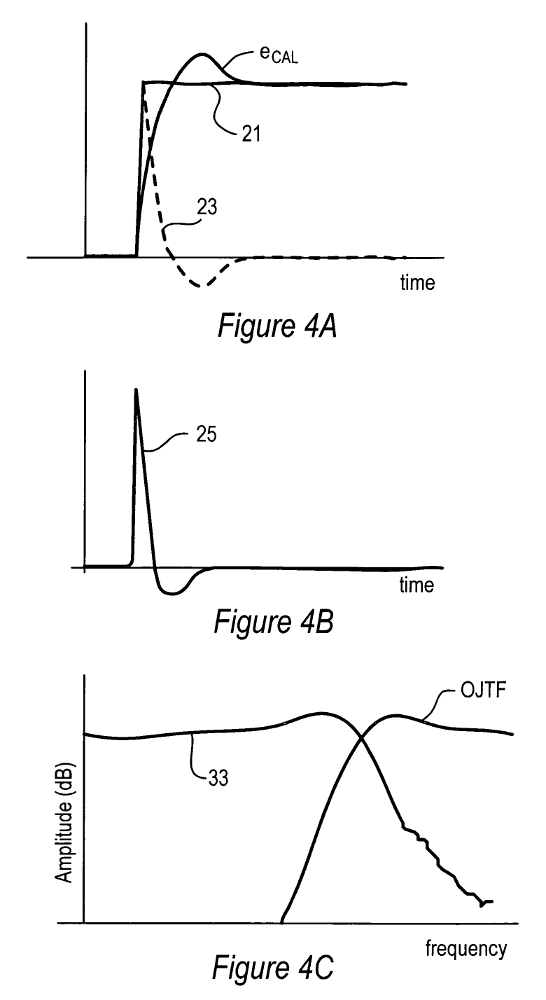

A calibration mode of the clock recovery system 10 enables the response characteristics of the PLL 18 within clock recovery system 10 to be characterized. Steps 32-36 of FIG. 3 provide an example illustration of the calibration mode of the clock recovery system implemented as a method 30 according to alternative embodiments of the present invention. Step 32 of the method 30 includes injecting a stimulus signal 21 into the signal summer 14 interposed between the phase detector 20 and the loop integrator 24 of the PLL 18. The stimulus signal 21 is injected into the signal summer 14 with the data signal 15 applied to a first input 1 of the phase detector 20 with the PLL 18 in a phase-locked state. In one example shown in FIG. 4A, the stimulus signal 21 includes a step signal that is provided by the signal source 12. In another example (not shown), the stimulus signal 21 includes an impulse signal that is provided by the signal source 12. In alternative examples of step 32, the stimulus signal 21 is any signal suitable for application to the signal summer 14 that has sufficient bandwidth to characterize the response characteristics of the PLL 18 in response to injection of the stimulus signal 21 into the signal summer 14.

Step 34 of the method 30 includes measuring a calibration error signal e_{CAL} at the output of the error amplifier 22 under the operating conditions of the PLL 18 established in step 32. In this example, the calibration error signal e_{CAL} is measured with the ADC 16 that is coupled to the signal path between the signal summer 14 and the loop integrator 24. When the stimulus signal 21 is a step signal, as shown in FIG. 4A, the calibration error signal e_{CAL} measured by the ADC 16 is as shown in FIG. 4A, superimposed on the step signal 21. In the example where the stimulus signal 21 is an impulse signal, the calibration error signal e_{CAL} measured by the ADC 16 provides the impulse response 25 of the PLL 18, as shown in FIG. 4B.

Step 34 also includes establishing a timing reference for measurements of the calibration error signal e_{CAL} that are acquired by the ADC 16. In one example the timing reference is established as shown in FIG. 2, by driving the ADC 16 and the signal source 12 with a common synchronization signal 27 that is provided by a timing generator 29. In an alternative example, a timing reference is established by coupling a second analog-to-digital converter (not shown) to the output of the signal source 12 to measure the stimulus signal 21 provided by the signal source 12. For this type of timing reference, the ADC 16 and the second analog-to-digital converter are strobed by a common timing signal. The measurement of the stimulus signal 21 acquired by the second analog-to-digital converter provides a timing reference from which measurements of the calibration error signal e_{CAL} by the ADC 16 can be acquired. Thus, for the example wherein the stimulus signal 21 is a step signal, the measurements of the calibration error signal e_{CAL} acquired by the ADC 16 are time-referenced to the rising edge of the step signal as measured by the second analog-to-digital converter coupled to the output of the signal source 12.

In step 36 of the method 30, the calibration error signal e_{CAL} that is measured in step 34 is processed, typically by a processor 31 coupled to the ADC 16, to determine one or more response characteristic of the PLL 18 in the clock recovery system 10. In one example, the processing in step 36 includes determining the step response 23 of the PLL 18 to a stimulus signal 21 that includes a step signal. The step response 23 can be determined as the normalized amplitude of the step signal 21 minus the calibration error signal e_{CAL} measured in step 34. An example of this determined step response 23 is shown in FIG. 4A. 10231 Another response characteristic of the PLL 18 is the closed loop gain, or jitter transfer function (JTF) of the PLL 18. The jitter transfer function, defined as the ratio of the jitter on the clock signal 11, φ_{CLK}, to the ratio of the jitter on the data signal 15, φ_{DATA}. The jitter transfer function can be determined according to the relationship JTF=1−e_{CAL}/φ_{DATA}.

Another response characteristic of the PLL 18 is the loop impulse response 25 of the PLL 18. In the example where the stimulus signal 21 includes the step signal, the loop impulse response 25 can be obtained as the derivative of the step response 23 that is shown in FIG. 4A. An example of the loop impulse response 25 of the PLL 18 is shown in FIG. 4B.

Another response characteristic of the PLL 18 within the clock recovery system 10 is the closed loop response 33 of the PLL 18, which can be obtained from the Fourier Transform of the loop impulse response 25. An example of the closed loop response 33 is shown in FIG. 4C.

Yet another response characteristic of the PLL 18 in the clock recovery system 10 is the observed jitter transfer function (OJTF). The observed jitter transfer function OJTF represents the jitter that results when the clock signal 11 recovered by the clock recovery system 10 is used to establish the timing of sample acquisitions of the data signal 15 that is applied to the clock recovery system 10. The observed jitter transfer function OJTF can be obtained from the jitter transfer function JTF according to the relationship OJTF =1−JTF. An example of the observed jitter transfer function OJTF is also shown in FIG. 4C.

According to alternative embodiments of the present invention, the clock recovery system 10 is included in a measurement instrument, such as a digital communication analyzer (DCA). In these embodiments, the observed jitter transfer function OJTF can be adjusted to provide an observed jitter transfer function OJTF_{INST} that accommodates for a trigger delay τ that is associated with the measurement instrument. This instrument observed jitter transfer function, OJTF_{INST}, can also be determined in step 36, according to the relationship OJTF_{INST}=1−JTF e^{-jwτ}. The instrument observed jitter transfer function OJTF_{INST} represents the jitter that results when the clock signal 11 recovered by the clock recovery system 10 is used to establish the timing of sample acquisitions of the data signal 15 by the measurement instrument within which the clock recovery system 10 is included.

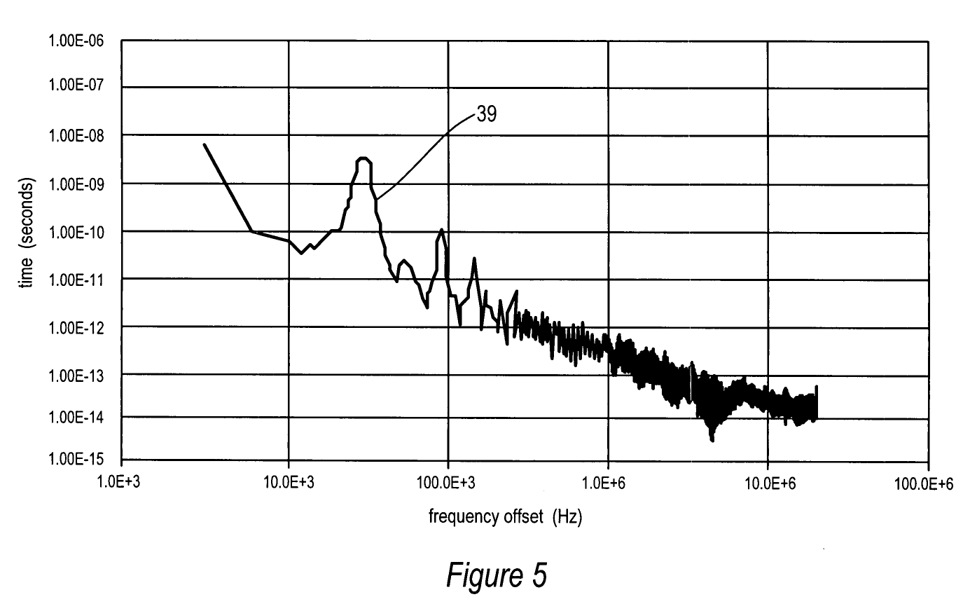

A measurement mode of the clock recovery system 10 is indicated in step 38 of the method 30 that is shown in FIG. 3. In the measurement mode, one or more of the response characteristics of the PLL 18 of the clock recovery system 10 that are determined in step 36 are applied to subsequent measurements acquired by the ADC 16. In the measurement mode, the signal source 12 does not inject a stimulus signal 21 to the signal summer 14 and the output of the phase detector 20 is provided to the error amplifier 22. The ADC 16 then acquires measurements of a measurement error signal e_{MEAS} at the output of the error amplifier 22 with the data signal 15 applied to the input 1 of the phase detector 20, with the clock signal 11 recovered from the data signal 15 applied to the input 2 of the phase detector 20, and with the PLL 18 in a phase locked state. This enables jitter characteristics of the data signal 15 to be determined independent of the response characteristics of the PLL 18 within the clock recovery system 10. FIG. 5 shows one example of a jitter characteristic of the data signal 15. In FIG. 5, the frequency spectrum 39 associated with the jitter of an example data signal 15 is determined from the Fourier Transform of the measured error signal eMEAS divided by the observed jitter transfer function OJTF of the PLL 18 within the clock recovery system 10. The frequency spectrum 39 indicates timing fluctuations of the data signal 15 at frequency offsets from the frequency of the clock signal 11 that is recovered from the data signal 15.

While the embodiments of the present invention have been illustrated in detail, it should be apparent that modifications and adaptations to these embodiments may occur to one skilled in the art without departing from the scope of the present invention as set forth in the following claims.

1. A clock recovery system, comprising:
a signal summer having a first input receiving a phase detected signal provided by a phase detector within a phase locked loop (PLL);
a signal source coupled to a second input of the signal summer selectively providing a stimulus signal to the signal summer; and
an analog-to-digital converter (ADC) coupled to a signal path between the signal summer and a loop integrator within the PLL.

2. The clock recovery system of claim 1 wherein the ADC measures a calibration error signal in the signal path with the signal source providing the stimulus signal to the signal summer with a data signal is applied to the phase detector, and with the PLL in a phase locked state.

3. The clock recovery system of claim 1 wherein the stimulus signal includes a step signal.

4. The clock recovery system of claim 3 wherein measurement of the calibration error signal by the ADC is time-referenced to a rising edge of the step signal.

5. The clock recovery system of claim 4 wherein the ADC is time-referenced by a common synchronization signal driving the ADC and the signal source.

6. The clock recovery system of claim 2 further comprising a processor coupled to the ADC, the processor determining at least one response characteristic of the PLL based on the calibration error signal measured by the ADC.

7. The clock recovery system of claim 6 wherein the at least one response characteristic of the PLL includes at least one of a step response of the PLL, an impulse response of the PLL, a Fourier Transform of the impulse response of the PLL, a closed loop frequency response of the PLL, and an observed jitter transfer function of the PLL.

8. The clock recovery system of claim 1 wherein the ADC measures a measurement error signal in the signal path with the signal source not injecting the stimulus signal to the signal summer, with a data signal applied to the phase detector at an input to the PLL and a clock signal recovered from the data signal applied to the phase detector from a feedback path of the PLL, and with the PLL in a phase locked state.

9. The clock recovery system of claim 8 further comprising a processor applying at least one response characteristic of the PLL to the measurement error signal, wherein the at least one response characteristic is determined by processing a calibration error signal measured in the signal path by the ADC with the signal source injecting the stimulus signal to the signal summer, with the data signal applied to the phase detector at an input to the PLL, and with the PLL in a phase locked state.

10. The clock recovery system of claim 9 wherein applying the at least one response characteristic of the PLL provides a frequency spectrum of jitter present on the data signal applied to the phase detector at the input to the PLL.

11. The clock recovery system of claim 9 wherein the clock signal recovered from the data signal is provided to a digital communication analyzer.

12. A clock recovery system, comprising:
selectively injecting a stimulus signal into a signal summer interposed between a phase detector and a loop integrator of a phase-locked loop (PLL), with a data signal applied to a first input of the phase detector and with the PLL in a phase locked state;
measuring a calibration error signal in a signal path of the PLL between the signal summer and the loop integrator when the stimulus signal is injected into the signal summer;
processing the measured calibration error signal to determine at least one response characteristic of the PLL; and
measuring a measurement error signal in the signal path when the stimulus signal is not injected into the signal summer, with a clock signal recovered from the data signal applied to a second input of the phase detector.

13. The clock recovery system of claim 12 further comprising applying the at least one response characteristic of the PLL to the measured measurement error signal to provide a frequency spectrum of jitter present on the data signal applied to the phase detector.

14. The clock recovery system of claim 12 wherein the stimulus signal includes a step signal.

15. The clock recovery system of claim 14 further including time-referencing measuring the calibration error signal to a rising edge of the step signal.

16. The clock recovery system of claim 12 wherein the at least one response characteristic includes at least one of a step response of the PLL, an impulse response of the PLL, a Fourier Transform of the impulse response of the PLL, a closed loop frequency response of the PLL, and an observed jitter transfer function of the PLL.

17. The clock recovery system of claim 16 wherein the at least one response characteristic includes an observed jitter transfer function for an instrument within which the clock recovery system is included.

18. The clock recovery system of claim 16 wherein the clock signal recovered from the data signal is applied to a digital communication analyzer and wherein the observed jitter transfer function accommodates a trigger delay associated with the digital communication analyzer.

19. The clock recovery system of claim 18 wherein the digital communication analyzer acquires samples of the data signal at acquisition times established by the clock signal recovered from the data signal.

20. The clock recovery system of claim 13 wherein applying the at least one response characteristic of the PLL to the measured measurement error signal dividing a Fourier Transform of the measurement error signal by an observed jitter transfer function of the PLL.
